(19) United States
(12) Patent Application Publication
(10) Pub. No.: US 2025/0022956 A1
(43) Pub. Date: Jan. 16, 2025

(54) STRESS LINERS IN SEMICONDUCTOR DEVICES

(71) Applicant: Taiwan Semiconductor Manufacturing Co., Ltd., Hsinchu (TW)

(72) Inventors: Yi-Cheng LI, Yunlin (TW); Jheng-Wei LIN, Hsinchu City (TW); Ta-Chun MA, New Taipei City (TW)

(73) Assignee: Taiwan Semiconductor Manufacturing Co., Ltd., Hsinchu (TW)

(21) Appl. No.: 18/513,116

(22) Filed: Nov. 17, 2023

Related U.S. Application Data
(60) Provisional application No. 63/526,244, filed on Jul. 12, 2023.

(51) Int. Cl. H01L 29/78; H01L 29/423; H01L 29/66; H01L 29/775; H01L 29/786

(52) U.S. Cl. CPC H01L 29/7843; H01L 29/42392; H01L 29/66439; H01L 29/775; H01L 29/785; H01L 29/78696

(57) ABSTRACT

A semiconductor device and a method of fabricating the semiconductor device are disclosed. The semiconductor device includes a substrate, a nanostructured channel region disposed on the substrate, a gate structure surrounding the nanostructured channel region, a source/drain (S/D) region disposed adjacent to the nanostructured channel region, an etch stop layer (ESL) disposed on the S/D region, a stress liner disposed on the etch stop layer and configured to provide compressive stress in the nanostructured channel region, an inter-layer dielectric (ILD) layer disposed on the stress liner, and a contact structure disposed in the S/D region, ESL, stress liner, and ILD layer.

### CROSS-REFERENCE TO RELATED APPLICATIONS

This application claims the benefit of U.S. Provisional Patent Application No. 63/526,244, titled “Mobility Enhancement of PFET via Inter-Layer Dielectric (ILD) Si Or SiGe Liner Stressor,” filed Jul. 12, 2023, which is incorporated by reference herein in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (finFETs). Such scaling down has increased the complexity of semiconductor manufacturing processes.

### BRIEF DESCRIPTION OF THE DRAWINGS

Aspects of this disclosure are best understood from the following detailed description when read with the accompanying figures.

FIG. 1A illustrates an isometric view of a semiconductor device with a stress liner, in accordance with some embodiments.

FIGS. 1B-1G illustrate different cross-sectional views of a semiconductor device with a stress liner, in accordance with some embodiments.

FIG. 2 is a flow diagram of a method for fabricating a semiconductor device with a stress liner, in accordance with some embodiments.

FIGS. 3A-11A and 3B-11B illustrate cross-sectional views of a semiconductor device with a stress liner at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5-20% of the value (e.g., ±1%, ±2%, ±3%, ±4%, ±5%, ±10%, ±10-15%, ±15˜20% of the value). These values are merely examples and are not intended to be limiting. The terms “about” and “substantially” can refer to a percentage of the values as interpreted by those skilled in relevant art(s) in light of the teachings herein.

The gate-all-around (GAA) transistor structures may be patterned by any suitable method. For example, the structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor structure.

The fin structures disclosed herein may be patterned by any suitable method. For example, the fin structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures.

The present disclosure provides example structures of p-type FETs (PFETs) with stress liners to enhance hole mobility in channel regions between adjacent source/drain (S/D) regions. With the use of stress liners, longitudinal compressive stress in the channel regions can be increased, which can increase the mobility of holes flowing in the channel regions. Increasing the hole mobility in the channel regions can improve the device performance.

In some embodiments, a PFET can include nanostructured channel regions, gate structures surrounding the nanostructured channel regions, and S/D regions on either sides of the nanostructured channel regions. The PFET can further include etch stop layers (ESLs), stress liners, and inter-layer dielectric (ILD) layers. In some embodiments, ESLs can be disposed on the S/D regions and along sidewalls of the gate structures. In some embodiments, the stress liners can be disposed on the ESLs and the ILD layers can be disposed on the stress liners. The stress liners exert pressure on the gate structures, which is transferred as longitudinal compressive stress in the nanostructured channel regions. In some embodiments, the stress liners can include a silicon oxide, a silicon germanium oxide, a germanium oxide, or other suitable oxides of a semiconductor material.

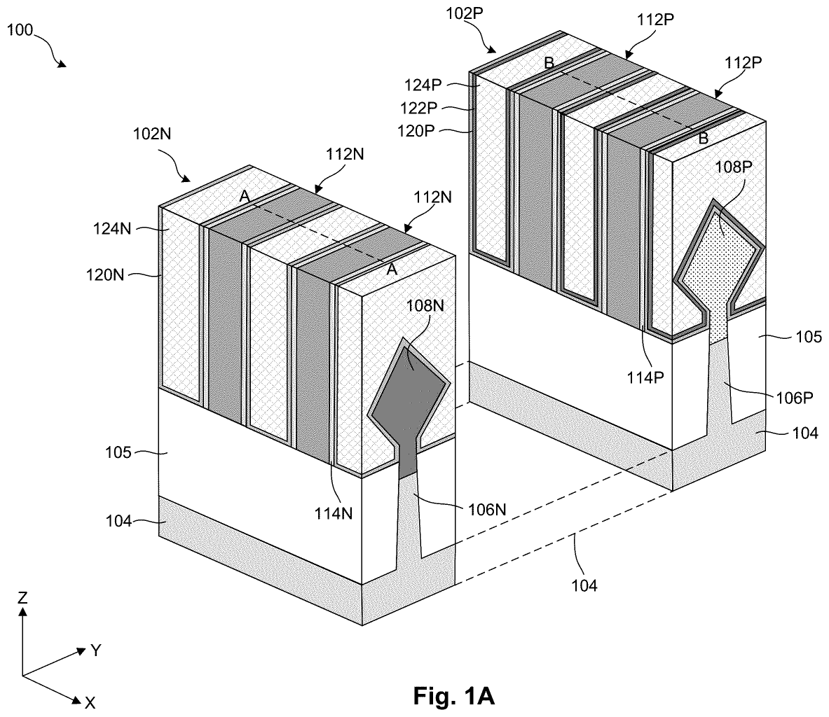

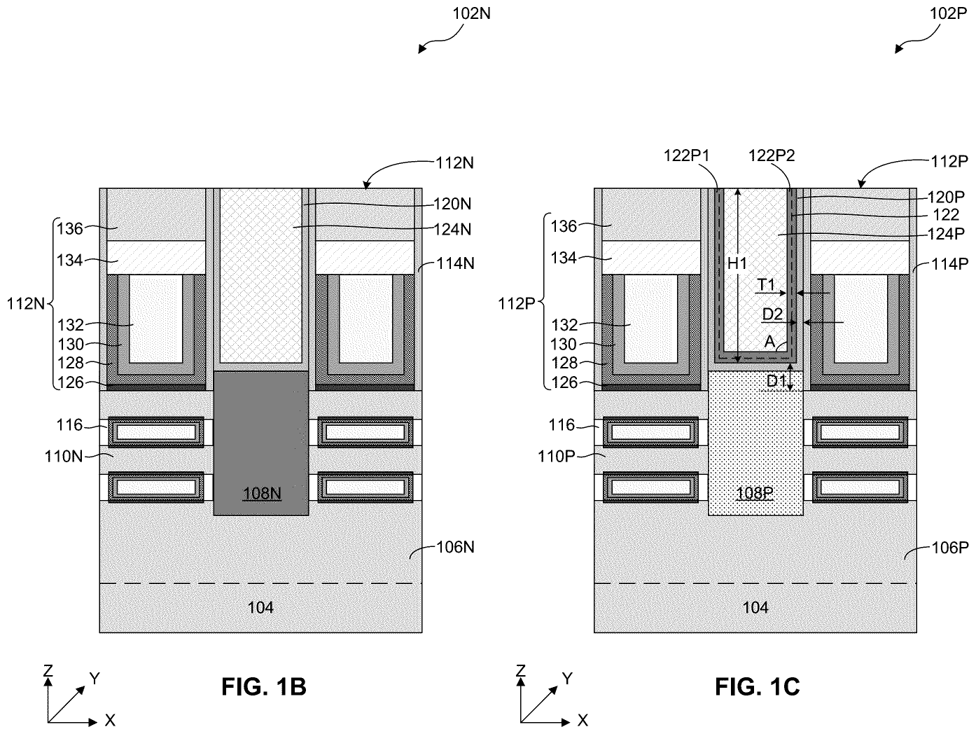

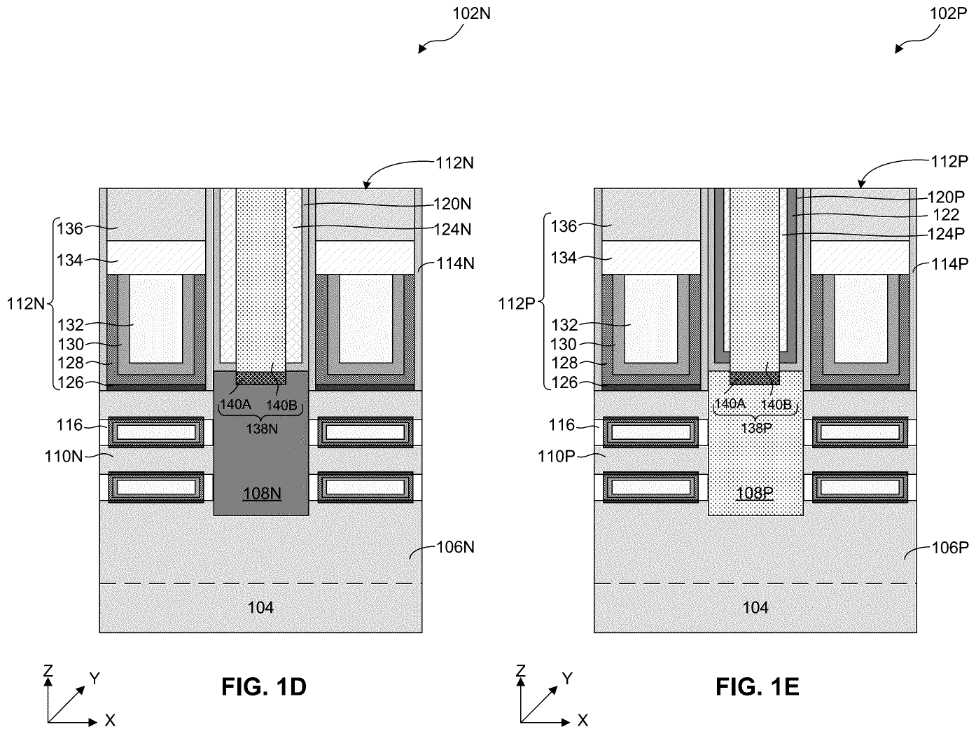

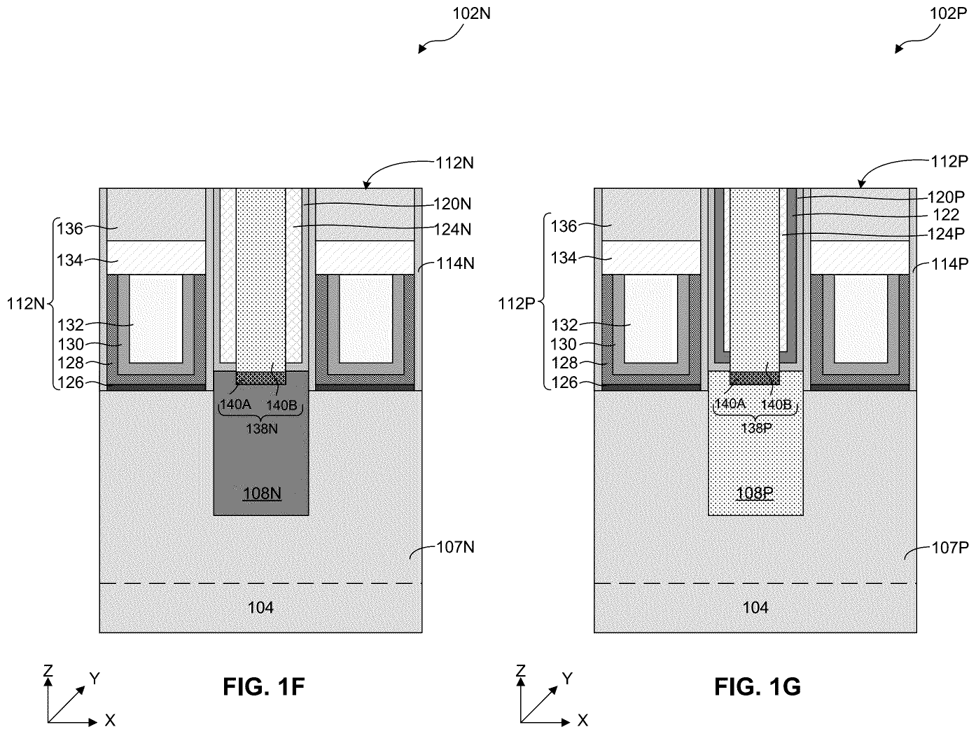

FIG. 1A illustrates an isometric view of a semiconductor device 100 with NFET 102N and PFET 102P, according to some embodiments. FIGS. 1B, 1D, and IF illustrate different cross-sectional views of NFET 102N along line A-A of FIG. 1A. FIGS. 1C, 1E, and 1G illustrate different cross-sectional views of PFET 102P along line B-B of FIG. 1A. FIGS. 1B-1G illustrate cross-sectional views with additional structures that are not shown in FIG. 1A for simplicity. The discussion of elements in FIGS. 1A-1G with the same annotations applies to each other, unless mentioned otherwise.

Semiconductor device 100 can be formed on a substrate 104 with NFET 102N and PFET 102P formed on different regions of substrate 104. There may be other FETs and/or structures (e.g., isolation structures) formed between NFET 102N and PFET 102P on substrate 104. In some embodiments, substrate 104 can be a semiconductor material, such as silicon, germanium (Ge), silicon germanium (SiGe), a silicon-on-insulator (SOI) structure, and a combination thereof. Further, substrate 104 can be doped with p-type dopants (e.g., boron, indium, aluminum, or gallium) or n-type dopants (e.g., phosphorus or arsenic). Semiconductor device 100 can further include shallow trench isolation (STI) regions 105 disposed on substrate 104. STI regions 105 can include an insulating material, such as silicon oxide (SiO₂), silicon nitride (SiN), silicon oxynitride (SiON), silicon oxycarbide (SiOC), silicon carbon nitride (SiCN), silicon oxycarbon nitride (SiOCN), and silicon germanium oxide (SiGeOₓ).

Referring to FIGS. 1A and 1B, in some embodiments, NFET 102N can include (i) a fin or sheet base 106N disposed on substrate 104, (ii) S/D regions 108N disposed on fin or sheet base 106N, (iii) nanostructured channel regions 110N disposed adjacent to S/D regions 108N, (iv) gate structures 112N surrounding nanostructured channel regions 110N, (v) outer gate spacers 114N disposed along sidewalls of gate structures 112N, (vi) inner gate spacers 116 disposed along sidewalls of S/D regions 108N, (vii) ESLs 120N disposed directly on S/D regions 108N, and (viii) ILD layers 124N disposed directly on ESLs 120N.

Similarly, referring to FIGS. 1A and 1C, in some embodiments, PFET 102P can include a fin or sheet base 106P disposed on substrate 104, (ii) S/D regions 108P disposed on fin or sheet base 106P, (iii) nanostructured channel regions 110P disposed adjacent to S/D regions 108P, (iv) gate structures 112P surrounding nanostructured channel regions 110P, (v) outer gate spacers 114P disposed along sidewalls of gate structures 112P, (vi) inner gate spacers 116 disposed along sidewalls of S/D regions 108P, (vii) ESLs 120P disposed directly on S/D regions 108N, (viii) stress liners 122 disposed directly on ESLs 120P, and (ix) ILD layers 124N disposed directly on stress liners 122. S/D regions 108N and 108P may refer to a source or a drain, individually or collectively dependent upon the context.

In some embodiments, fin or sheet base 106N can include a material similar to substrate 104. Fin or sheet base 106N can have elongated sides extending along an X-axis. S/D regions 108N can include an epitaxially-grown semiconductor material, such as Si, and n-type dopants, such as phosphorus and other suitable n-type dopants. S/D regions 108P can include an epitaxially-grown semiconductor material, such as Si and SiGe, and p-type dopants, such as boron and other suitable p-type dopants.

As used herein, the term “nanostructured” defines a structure, layer, and/or region as having a horizontal dimension (e.g., along an X- and/or Y-axis) and/or a vertical dimension (e.g., along a Z-axis) less than about 100 nm, for example about 90 nm, about 50 nm, about 10 nm, or other values less than about 100 nm. In some embodiments, nanostructured channel regions 110N and 110P can be in the form of nanosheets, nanowires, nanorods, nanotubes, or other suitable nanostructured shapes. Nanostructured channel regions 110N and 110P can include semiconductor materials similar to or different from substrate 104. In some embodiments, nanostructured channel regions 110N and 110P can include Si, silicon arsenide (SiAs), silicon phosphide (SiP), silicon carbide (SiC), silicon carbon phosphide (SiCP), silicon germanium (SiGe), silicon germanium boron (SiGeB), germanium boron (GeB), silicon germanium stannum boron (SiGeSnB), a III-V semiconductor compound, or other suitable semiconductor materials. In some embodiments, each of nanostructured channel regions 110N and 110P can have a thickness of about 3 nm to about 15 nm along a Z-axis. Though two nanostructured channel regions 110N are shown under each gate structure 112N and two nanostructured channel regions 110P are shown under each gate structure 112P, the number of nanostructured channel regions 110N can be 1 through 5 and the number of nanostructured channel regions 110P can be 1 through 5. Though rectangular cross-sections of nanostructured channel regions 110N and 110P are shown, nanostructured channel regions 110N and 110P can have cross-sections of other geometric shapes (e.g., circular, elliptical, triangular, or polygonal).

Each of gate structures 112N and 112P can be a multi-layered structure and can surround nanostructured channel regions 110N and 110P, respectively, for which gate structures 112N and 112P can be referred to as “GAA structures.” In some embodiments, a gate pitch can be about 30 nm to about 100 nm. The gate pitch is defined as a sum of a distance along an X-axis between adjacent gate structures with equal gate lengths and a gate length of one of the adjacent gate structures. In some embodiments, each of gate structures 112N and 112P can include (i) an interfacial oxide (IL) layer 126, (ii) a high-k (HK) gate dielectric layer 128 disposed on IL layer 126, (iii) a work function metal (WFM) layer 130 disposed on HK gate dielectric layer 128, (iv) a gate metal fill layer 132 disposed on WFM layer 130, (v) a conductive capping layer 134 disposed on gate metal fill layer 132, and (vi) an insulating capping layer 136 disposed on conductive capping layer 136.

In some embodiments, IL layer 126 can include SiO₂, SiGeOₓ, or germanium oxide (GeOₓ). In some embodiments, HK gate dielectric layer 128 can include a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), and zirconium silicate (ZrSiO₂). In some embodiments, WFM layer 130 can include titanium aluminum (TiAl), titanium aluminum carbide (TiAlC), tantalum aluminum (TaAl), tantalum aluminum carbide (TaAlC), Al-doped Ti, Al-doped TiN, Al-doped Ta, Al-doped TaN, or other suitable Al-based materials for NFET 102N. In some embodiments, WFM layer 130 can include substantially Al-free (e.g., with no Al) Ti-based or Ta-based nitrides or alloys, such as titanium nitride (TiN), titanium silicon nitride (TiSiN), titanium gold (Ti—Au) alloy, titanium copper (Ti—Cu) alloy, tantalum nitride (TaN), tantalum silicon nitride (TaSiN), tantalum gold (Ta—Au) alloy, and tantalum copper (Ta—Cu) for PFET 102P. In some embodiments, gate metal fill layer 132 can include a suitable conductive material, such as tungsten (W), titanium (Ti), silver (Ag), ruthenium (Ru), molybdenum (Mo), copper (Cu), cobalt (Co), Al, iridium (Ir), nickel (Ni), metal alloys, and a combination thereof.

Insulating capping layer 136 can protect the underlying conductive capping layers 134 from structural and/or compositional degradation during subsequent processing of the semiconductor device 100. In some embodiments, insulating capping layer 136 can include a nitride material, such as SiN, and can have a thickness of about 5 nm to about 10 nm for adequate protection of the underlying conductive capping layers 134.

Conductive capping layer 134 can provide a conductive interface between gate metal fill layer 132 and a gate contact structure (not shown) to electrically connect gate metal fill layer 132 to the gate contact structure without forming the gate contact structure directly on or in gate metal fill layer 132. The gate contact structure is not formed directly on or in gate metal fill layer 132 to prevent contamination by any of the processing materials used in the formation of the gate contact structure. Contamination of gate metal fill layer 132 can lead to the degradation of device performance. Thus, with the use of conductive capping layer 134, gate structures 112N and 112P can be electrically connected to the gate contact structure without compromising the integrity of gate structures 112N and 112P. In some embodiments, conductive capping layer 134 can include a metallic material, such as W, Ru, Mo, Co, other suitable metallic materials, and a combination thereof.

In some embodiments, gate structures 112N can be electrically isolated from adjacent S/D regions 108N by outer gate spacers 114N and gate structures 112P can be electrically isolated from adjacent S/D regions 108P by outer gate spacers 114P. In some embodiments, outer gate spacers 114N and 114P can include an insulating material, such as SiO₂, SiN, SiCN, SiOCN, and a combination thereof. In some embodiments, the portions of gate structures 112N surrounding nanostructured channel regions 110N can be electrically isolated from adjacent S/D regions 108N by inner spacers 116. Similarly, the portions of gate structures 112P surrounding nanostructured channel regions 110P can be electrically isolated from adjacent S/D regions 108P by inner spacers 116. Inner spacers 116 can include an insulating material, such as SiOₓ, SiN, SiCN, SiOCN, and a combination thereof.

In some embodiments, ESLs 120N and 120P can have a dielectric constant of about 4 to about 7. In some embodiments, ESLs 120N and 120P can include a dielectric material, such as lanthanum oxide (LaO), aluminum oxide (Al₂O₃), yttrium oxide (Y₂O₃), tantalum carbon nitride (TaCN), zirconium silicide (ZrSi), SiOCN, SiOC, SiCN, zirconium nitride (ZrN), zirconium aluminum oxide (ZrAlO), TiO₂, Ta₂O₃, ZrO₂, HfO₂, SiN, hafnium silicide (HfSi), aluminum oxynitride (AlON), SiO₂, SiC, SiN, and zinc oxide (ZnO).

In some embodiments, stress liners 122 can be disposed directly on ESLs 120P and can be configured to provide longitudinal compressive stress in nanostructured channel regions 110P during the formation of stress liners 122, described in detail below. In some embodiments, stress liner 122 can include a dielectric material, such as SiOₓ, SiGeOₓ, GeOₓ, or other oxides of semiconductor material. In some embodiments, stress liner 122 can further include carbon, nitrogen, and/or fluorine atoms, each of which can have a concentration of about 0.1 atomic % to about 5 atomic %. In some embodiments, stress liner 122 can include a Ge-free Si-based oxide layer or a Si-free Ge-based oxide layer. In some embodiments, stress liner 122 can include a SiGe-based oxide layer with a concentration of Ge atoms of about 1 atomic % to about 50 atomic %.

In some embodiments, the concentration of silicon and/or germanium atoms can be greater in liner portion 122P1 than in liner portion 122P2. In some embodiments, the concentration of oxygen atoms can be greater in liner portion 122P2 than in liner portion 122P1. In some embodiments, the concentration of silicon and/or germanium atoms can be greater than the concentration of oxygen atoms in liner portion 122P1 and the concentration of oxygen atoms can be greater than the concentration of silicon and/or germanium atoms in liner portion 122P2. In some embodiments, liner portion 122P1 can include a non-oxidized Si, Ge, or SiGe layer (e.g., oxygen-free Si, Ge, or SiGe layer) and liner portion 122P2 can include an oxidized Si, Ge, or SiGe layer (e.g., SiOₓ, SiGeOₓ, or GeOₓ).

In some embodiments, stress liner 122 can have a height H1 of about 5 nm to about 30 nm and a thickness T1 of about 2 nm to about 10 nm. In some embodiments, a bottom surface of stress liner 122 can be disposed at a distance D1 of about 15 nm to about 25 nm above a top surface of the topmost nanostructured channel regions 110P. In some embodiments, stress liner 122 can be laterally separated from outer gate spacers 114P by a distance D2 of about 2 nm to about 10 nm. Within these ranges of height H1, thickness T1, and distances D1 and D2, stress liners 122 can adequately provide the longitudinal compressive stress in nanostructured channel regions 110P to enhance the mobility of holes in nanostructured channel regions 110P for improving performance of PFET 102P. Though FIG. 1C shows the sidewalls of stress liner 122 to form an angle A of about 90 degrees with the horizontal bottom portion of stress liner, the angle A can range from about 90 degrees to about 165 degrees, according to some embodiments.

In some embodiments, ILD layers 124N can be disposed directly on ESL 120N (shown in FIG. 1B) and ILD layer 124P can be disposed directly on stress liner 122 (shown in FIG. 1C). In some embodiments, ILD layers 124N and 124P can include an insulating material, such as SiO₂, SiN, SION, SiCN, and SiOCN. In some embodiments, top surfaces of ILD layer 124P, stress liner 122, ESL 120P, and insulating capping layer 136 can be substantially coplanar with each other. In some embodiments, the materials of ESL 120P, stress liner 122, and ILD layer 124P can be different from each other. In some embodiments, the materials of ESL 120P and ILD layer 124P can be the same, but different from the material of stress liner 122. In some embodiments, stress liner 122 can include Ge-based oxide layer. ESL 120P and ILD layer 124P can include Ge-free oxide or nitride layers, according to some embodiments.

Referring to FIGS. 1D and 1E, in some embodiments, NFET 102N and PFET 102P can further include S/D contact structures 138N and 138P, respectively. S/D contact structures 138N and 138P can include (i) silicide layers 140A, and (ii) contact plugs 140B disposed on silicide layers 140A. Silicide layers 140A can be disposed in S/D regions 108N and 108P. Contact plug 140B of S/D contact structure 138N can extend through ILD layer 124N and ESL 120N and can be disposed on silicide layer 140A, as shown in FIG. 1D. Contact plug 140B of S/D contact structure 138P can extend through ILD layer 124P, stress liner 122, and ESL 120P and can be disposed on silicide layer 140A, as shown in FIG. 1E. Sidewalls of stress liner 122 can be in contact with contact plug 140B of S/D contact structure 138P.

In some embodiments, silicide layer 140A in NFET 102N can include titanium silicide (TiₓSi_{y}), tantalum silicide (TaₓSi_{y}), molybdenum (MoₓSi_{y}), zirconium silicide (ZrₓSi_{y}), hafnium silicide (HfₓSi_{y}), scandium silicide (ScₓSi_{y}), yttrium silicide (YₓSi_{y}), terbium silicide (TbₓSi_{y}), lutetium silicide (LuₓSi_{y}), erbium silicide (ErₓSi_{y}), ybtterbium silicide (YbₓSi_{y}), europium silicide (EuₓSi_{y}), thorium silicide (ThₓSi_{y}), other suitable metal silicide materials, or a combination thereof. In some embodiments, silicide layer 140A in PFET 102P can include nickel silicide (NiₓSi_{y}), cobalt silicide (CoₓSi_{y}), manganese silicide (MnₓSi_{y}), tungsten silicide (WₓSi_{y}), iron silicide (FeₓSi_{y}), rhodium silicide (RhₓSi_{y}), palladium silicide (PdₓSi_{y}), ruthenium silicide (RuₓSi_{y}), platinum silicide (PtₓSi_{y}), iridium silicide (IrₓSi_{y}), osmium silicide (OsxSiy), other suitable metal silicide materials, or a combination thereof.

In some embodiments, contact plugs 140B can include conductive materials with low resistivity (e.g., resistivity of about 50μΩ-cm, about 40μΩ-cm, about 30μΩ-cm, about 20 μΩ-cm, or about 10 μΩ-cm), such as Co, W, Ru, Al, Mo, iridium (Ir), nickel (Ni), Osmium (Os), rhodium (Rh), other suitable conductive materials with low resistivity, and a combination thereof.

Referring to FIGS. 1F and 1G, in some embodiments, NFET 102N and PFET 102P can be finFETs, instead of GAA FETs (shown in FIGS. 1B-1E), and can have fin structures 107N and 107P instead of nanostructured channel regions 110N and 110P and fin bases 106N-106P. Unlike GAA FET, finFET can have gate structures 112N and 112P disposed on fin structures 107N and 107P, respectively. The fin regions of fin structures 107N and 107P underlying gate structures 112N and 112P and adjacent to S/D regions 106N and 106P can function as channel regions. Stress liner 122 can provide longitudinal compressive stress in the fin regions of fin structure 107P.

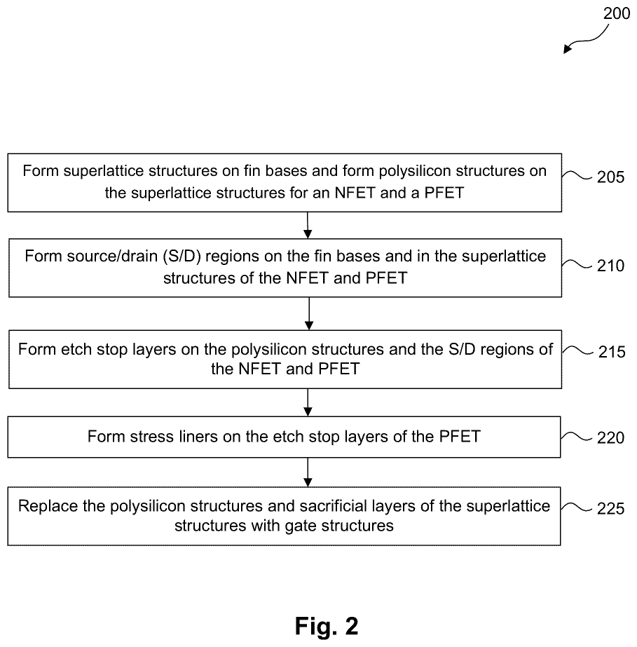

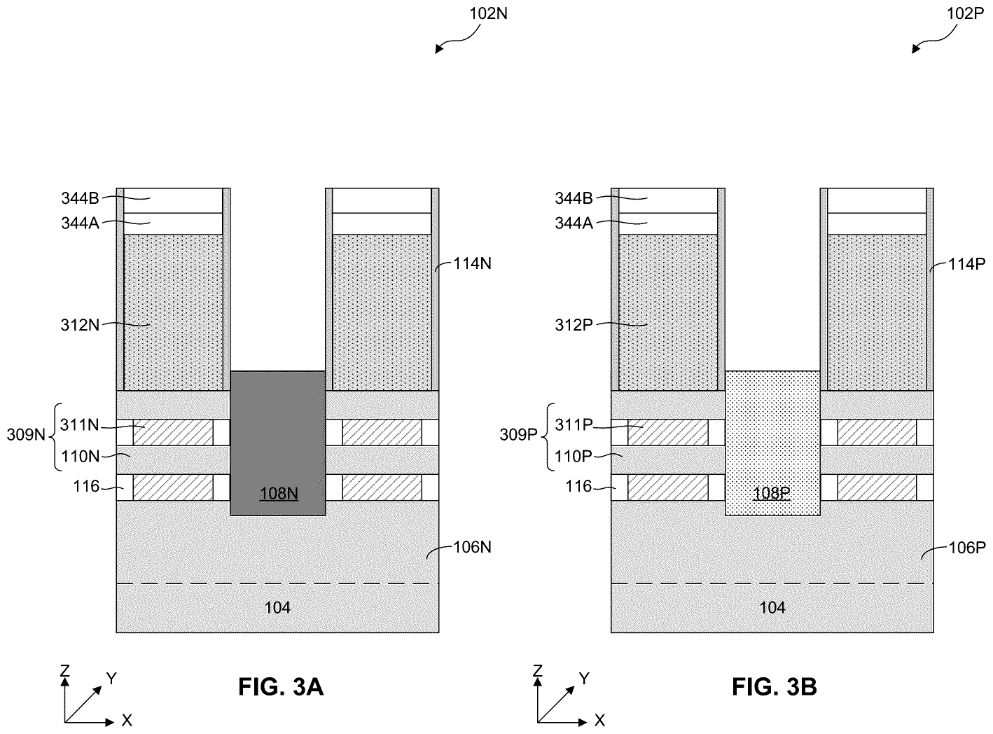

FIG. 2 is a flow diagram of an example method 200 for fabricating semiconductor device 100 with NFET 102N and PFET 102P as described above with reference to FIGS. 1A-1C, according to some embodiments. For illustrative purposes, the operations illustrated in FIG. 2 will be described with reference to the example fabrication process for fabricating semiconductor device 100 as illustrated in FIGS. 3A-11A and 3B-11B. FIGS. 3A-11A are cross-sectional views of NFET 102N along line A-A of FIG. 1A at various stages of fabrication, according to some embodiments. FIGS. 3B-11B are cross-sectional views of PFET 102P along line B-B of FIG. 1A at various stages of fabrication, according to some embodiments. Operations can be performed in a different order or not performed depending on specific applications. It should be noted that method 200 may not produce a complete semiconductor device 100. Accordingly, it is understood that additional processes can be provided before, during, and after method 200, and that some other processes may only be briefly described herein. The discussion of elements in FIGS. 1A-1C, 3A-11A, and 3B-11B with the same annotations applies to each other, unless mentioned otherwise.

Referring to FIG. 2, in operation 205, superlattice structures are formed on fin bases, and polysilicon structures are formed on the superlattice structures for an NFET and a PFET. For example, as described with reference to FIGS. 3A and 3B, superlattice structures 309N and 309P (also referred to as “nanosheet stacks 309N and 309P”) are formed on fin bases 106N and 106P, respectively, and polysilicon structures 312N and 312P are formed on superlattice structures 309N and 309P, respectively. In some embodiments, hard mask layers 344A and 344B can be formed during the formation of polysilicon structures 312N and 312P. Superlattice structure 309N can include nanostructured layers 110N and 311N arranged in an alternating configuration. Similarly, superlattice structure 309P can include nanostructured layers 110P and 311P arranged in an alternating configuration. In some embodiments, nanostructured layers 110N and 110P can include Si and nanostructured layers 311N and 311P can include SiGe. In some embodiments, each of nanostructured layers 110N, 311N, 110P, and 311P can have a thickness of about 3 nm to about 15 nm along a Z-axis. Nanostructured layers 311N and 311P are also referred to as “sacrificial layers 311N and 311P.” During subsequent processing, polysilicon structures 312N and 312P and sacrificial layers 311N and 311P can be replaced with gate structures 112N and 112P in a gate replacement process.

Referring to FIG. 2, in operation 210, S/D regions are formed on the fin bases and in the superlattice structures of the NFET and PFET. For example, as described with reference to FIGS. 3A and 3B, S/D regions 108N and 108P are formed in superlattice structures 309N and 309P and on fin bases 106N and 106P. The formation of S/D regions 108N and 108P can include sequential operations of (i) forming S/D openings (not shown) in superlattice structures 309N and 309P, (ii) depositing a first hard mask layer (not shown) on NFET 102N and PFET 102P, (iii) removing the first hard mask layer from PFET 102P, (iv) epitaxially growing a semiconductor material with p-type dopants in S/D openings of PFET 102P, as shown in FIG. 3B, (v) removing the first hard mask layer from NFET 102N, (vi) depositing a second hard mask layer (not shown) on NFET 102N and PFET 102P, (vii) removing the second hard mask layer from NFET 102N, (viii) epitaxially growing a semiconductor material with n-type dopants in S/D openings of NFET 102N, as shown in FIG. 3A, and (ix) removing the second hard mask layer from PFET 102P. In some embodiments, inner spacers 116 can be formed after the formation of S/D openings in NFET 102N and PFET 102P, and prior to the deposition of the first hard mask layer on NFET 102N and PFET 102P.

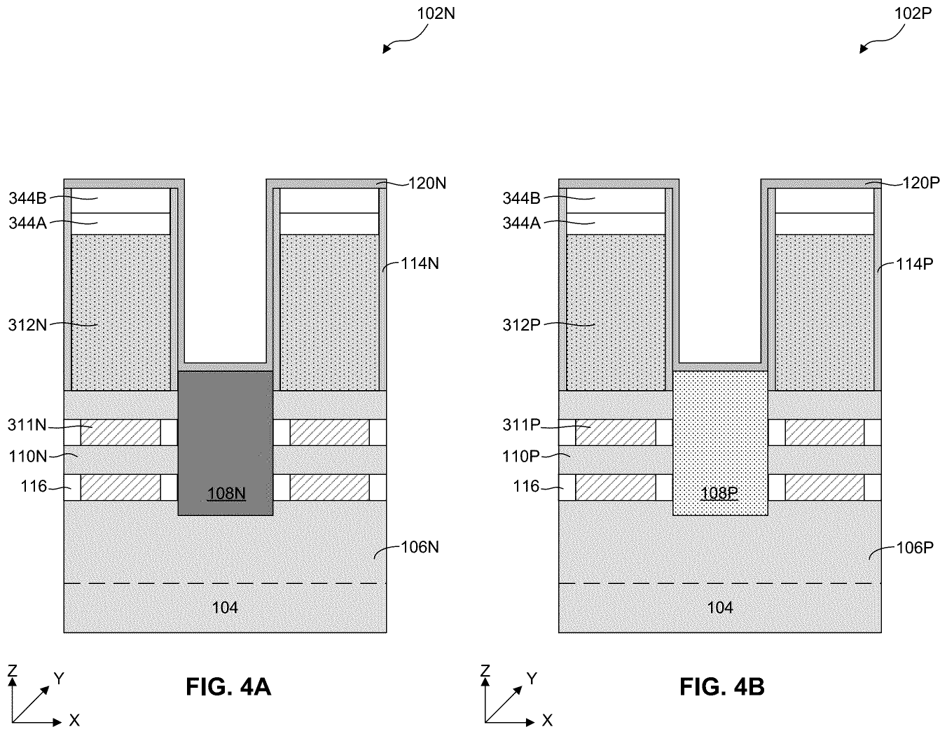

Referring to FIG. 2, in operation 215, ESLs are formed on the polysilicon structures and S/D regions of the NFET and PFET. For example, as described with reference to FIGS. 4A and 4B, ESLs 120N and 120P are formed on polysilicon structures 312N and 312P and on S/D regions 108N and 108P. The formation of ESLs 120N and 120P can include depositing a dielectric layer of LaO, Al₂O₃, Y₂O₃, TaCN, ZrSi, SiOCN, SiOC, SiCN, ZrN, ZrAlO, TiO₂, Ta₂O₃, ZrO₂, HfO₂, SiN, HfSi, AlON, SiO₂, SiC, SiN, or ZnO on the structures of FIGS. 3A and 3B to form the structures of FIGS. 4A and 4B.

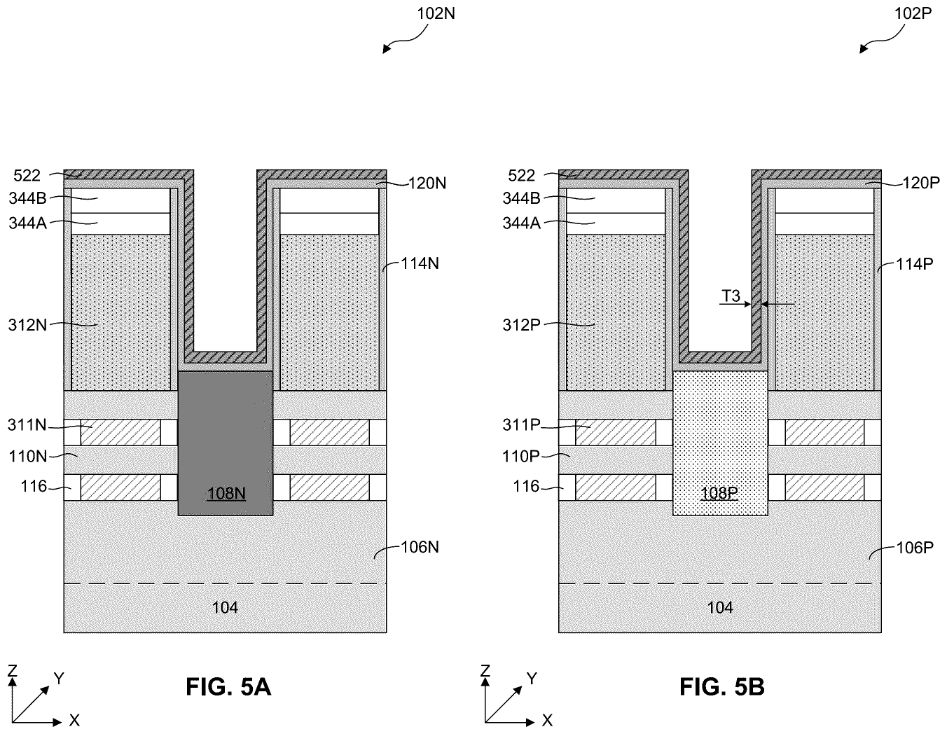

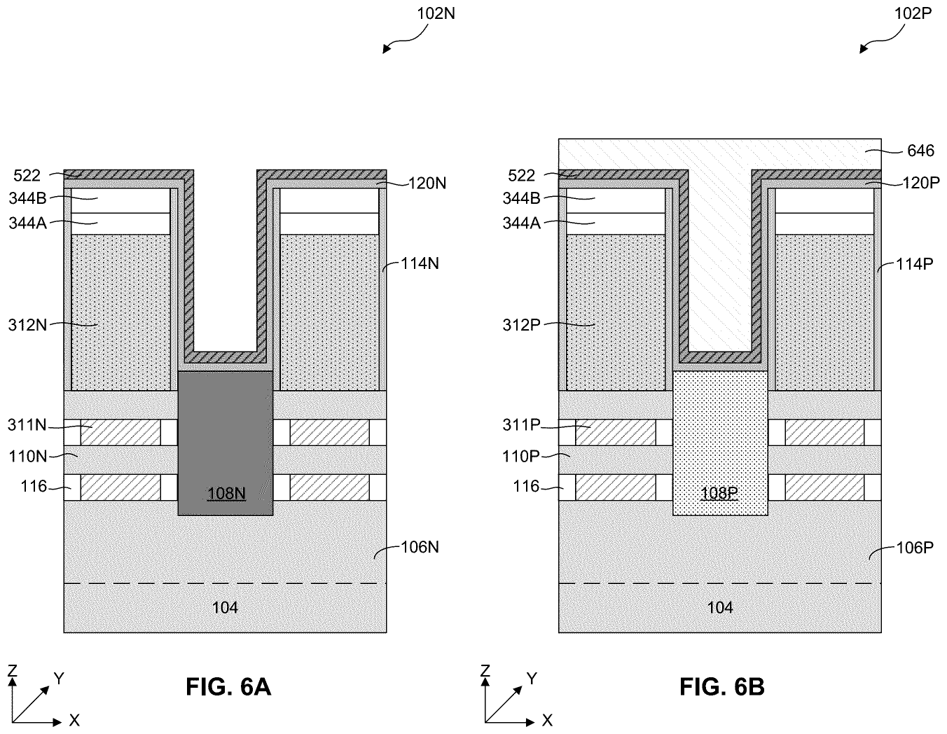

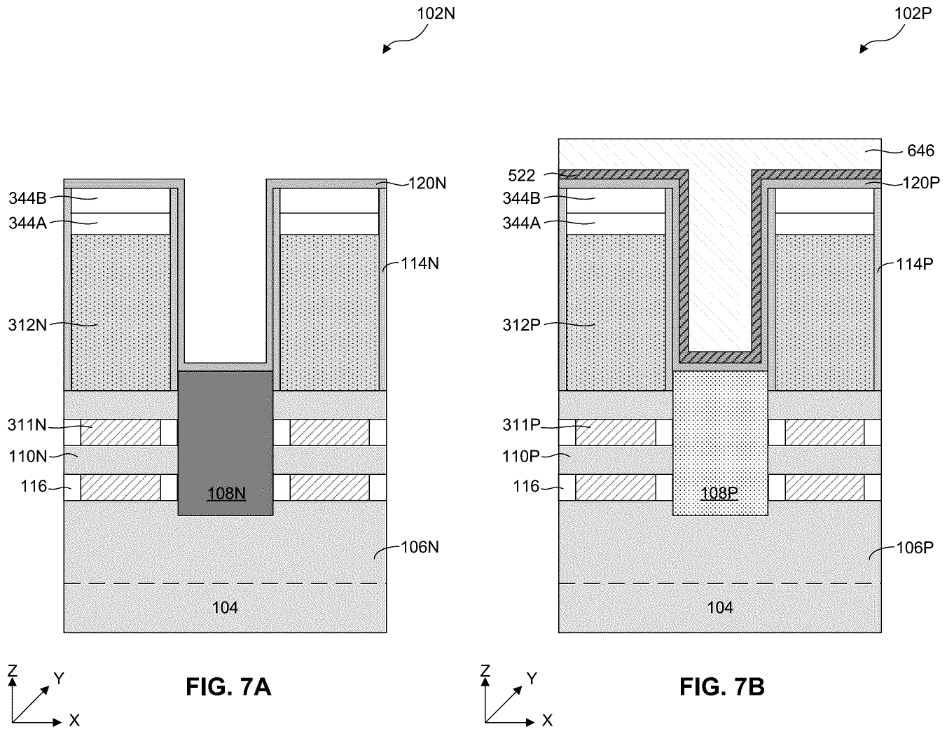

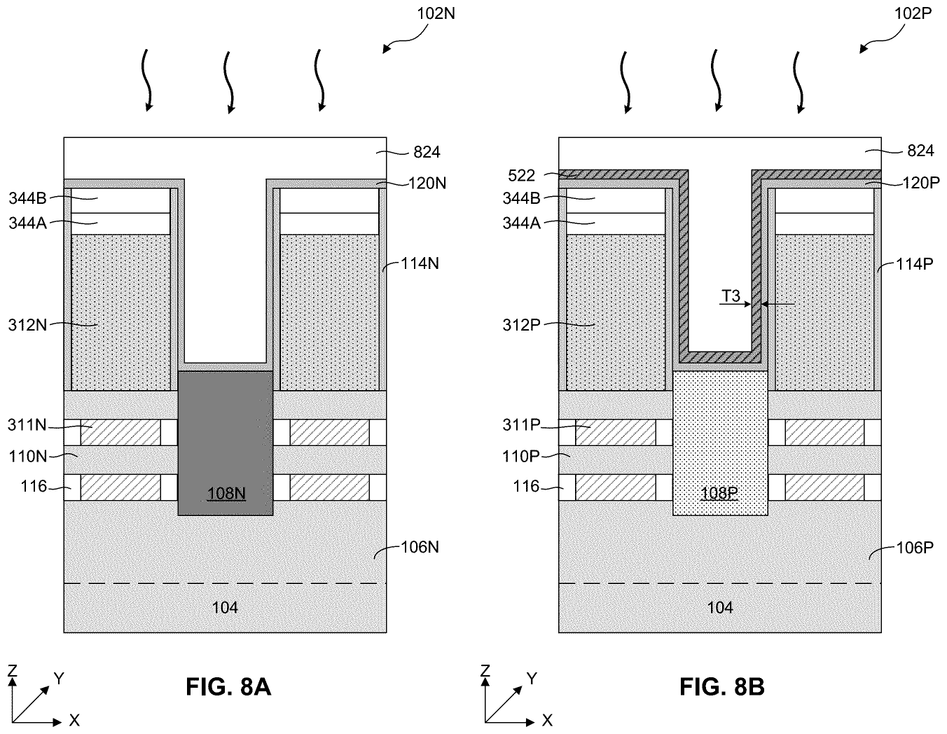

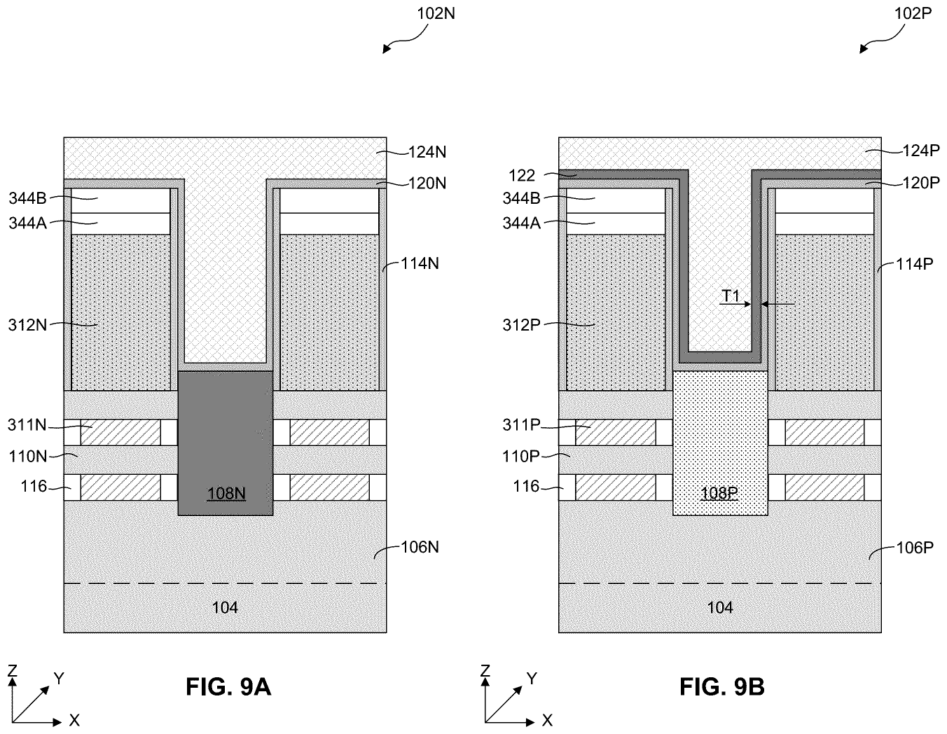

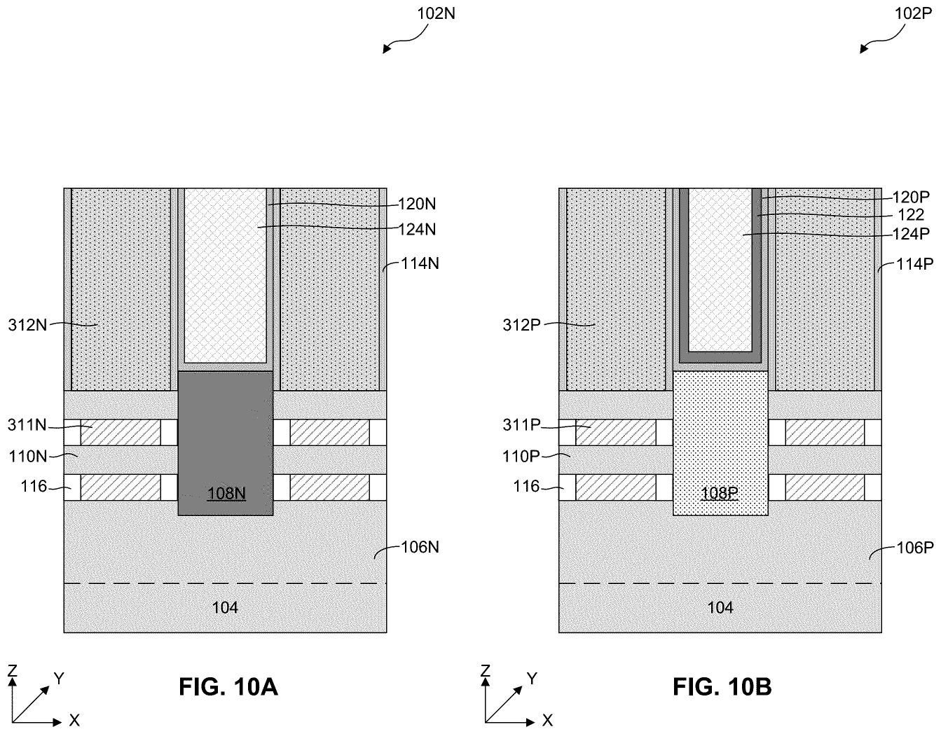

Referring to FIG. 2, in operation 220, stress liners are formed on the ESLs of the PFET. For example, as described with reference to FIGS. 5A-10A and 5B-10B, stress liner 122 is selectively formed on ESL 120P of PFET 102P and is not formed on ESL 120N of NFET 102N. The formation of stress liner 122 can include sequential operations of (i) depositing a semiconductor layer 522 directly on ESLs 120N and 120P with a thickness T3, as shown in FIGS. 5A and 5B, (ii) forming a masking layer 646 on the portion of semiconductor layer 522 in PFET 102P, as shown in FIG. 6B, (iii) etching the portion of semiconductor layer 522 from NFET 102N, as shown in FIG. 7A, (iv) removing masking layer 646 from PFET 102P, as shown in FIG. 8B, (v) depositing a flowable dielectric layer 824 directly on ESL 120N and directly on semiconductor layer 522, as shown in FIGS. 8A and 8B, (vi) performing a thermal anneal process on the structures of FIGS. 8A and 8B to form stress liner 122 and ILD layers 124N and 124P, as shown in FIGS. 9A and 9B, and (vii) performing a chemical mechanical polishing (CMP) process on the structures of FIGS. 9A and 9B to substantially coplanarize top surfaces of ESLs 120N and 120P, stress liner 122, and ILD layers 124N and 124P with top surfaces of polysilicon structures 312N and 312P, as shown in FIGS. 10A and 10B.

In some embodiments, semiconductor layer 522 can include an amorphous Si layer, an amorphous Ge layer, or a SiGe layer. In some embodiments, semiconductor layer 522 can include a SiGe layer with a concentration of Ge atoms of about 1 atomic % to about 50 atomic %. In some embodiments, semiconductor layer 522 can be deposited using one or more precursor gases from silane (SiH₄), disilane (Si₂H₆), germane (GeH₄), dichlorosilane (SiH₂Cl₂), or other suitable higher order of silane (SiₓH₂ₓ₊₂). In some embodiments, semiconductor layer 522 can be deposited at a temperature of about 300° C. to about 600° C. and at a pressure of about 0.1 torr to about 10 torr.

In some embodiments, the thermal anneal process can be performed at a temperature of about 400° C. to about 700° C. During the thermal anneal process, flowable dielectric layer 824 can be densified to form ILD layers 124N and 124P, as shown in FIGS. 9A and 9B. At the same time, oxygen atoms from flowable dielectric layer 824 can oxidize semiconductor layer 522 to form stress liner 122 during the thermal anneal process, as shown in FIG. 9B. Due to the oxidation of semiconductor layer 522, the volume of semiconductor layer 522 can expand. As a result, stress liner 122 can have a thickness T1 greater than a thickness T3 of semiconductor layer 522. In addition, due to the expanded volume, stress liner 122 can exert longitudinal and lateral pressure on polysilicon structure 312P of PFET 102P. The longitudinal and lateral pressure on polysilicon structure 312P can be transferred as longitudinal compressive stress in nanostructured channel regions 110P.

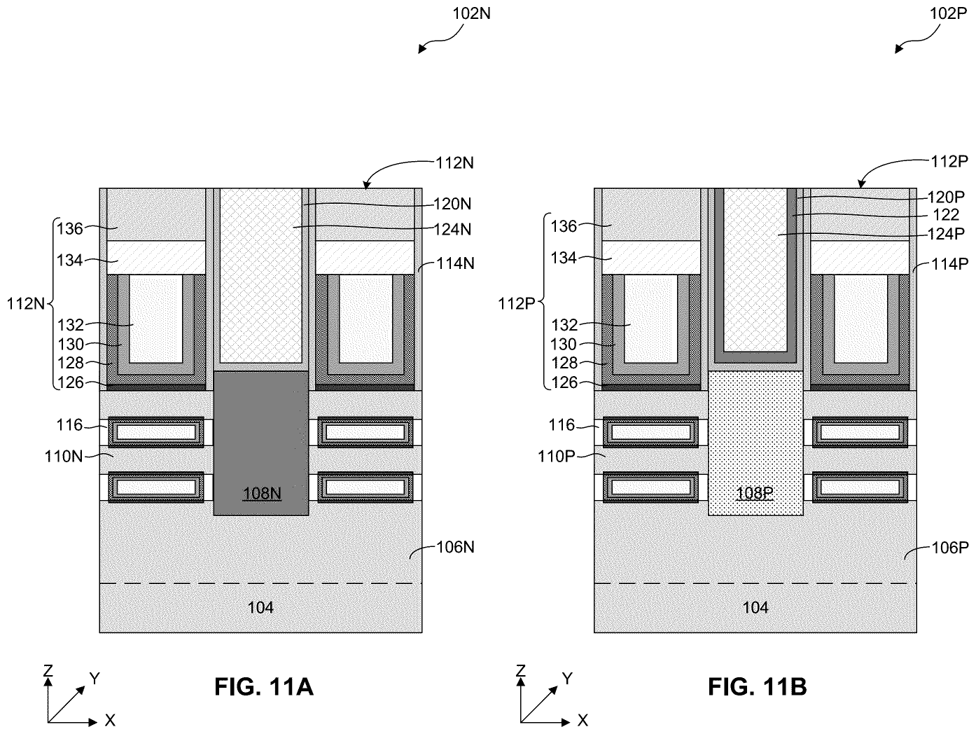

Referring to FIG. 2, in operation 225, the polysilicon structures and sacrificial layers of the superlattice structures are replaced with gate structures. For example, as described with reference to FIGS. 11A and 11B, polysilicon structures 312N and 312P and sacrificial layers 311N and 311P are replaced with gate structures 112N and 112P. The formation of gate structures 112N and 112P can include removing polysilicon structures 312N and 312P and sacrificial layers 311N and 311P from the structures of FIGS. 10A and 10B to form gate openings (not shown), and forming gate structures 112N and 112P in the gate openings, as shown in FIGS. 11A and 11B. In some embodiments, the formation of gate structures 112N and 112P can be followed by the formation of S/D contact structures 138N and 138P, as shown in FIGS. 1D and 1E.

In some embodiments, operations similar to operations 205-225 of method 200 can be used to fabricate finFETs of FIGS. 1F and 1G, except (i) fin structures 107N and 107P are formed, instead of superlattice structures 309N and 309P on fin bases 106N and 106P in operation 205, (ii) S/D regions 108N and 108P are formed in fin structures 107N and 107P, instead of superlattice structures 309N and 309P in operation 210, and (ii) sacrificial layers 311N and 311P are absent and are not replaced with gate structures 112N and 112P in operation 225.

The present disclosure provides example structures of PFETs (e.g., PFET 102P) with stress liners (e.g., stress liners 122) to enhance hole mobility in channel regions (e.g., nanostructured channel regions 110P) between adjacent S/D regions (e.g., S/D regions 108). With the use of stress liners, longitudinal compressive stress in the channel regions can be increased, which can increase the mobility of holes flowing in the channel regions. Increasing the hole mobility in the channel regions can improve the device performance.

In some embodiments, a PFET can include nanostructured channel regions, gate structures (e.g., gate structures 112P) surrounding the nanostructured channel regions, and S/D regions on either sides of the nanostructured channel regions. The PFET can further include ESLs (e.g., ESL 120P), stress liners, and ILD layers (e.g., ILD layers 124P). In some embodiments, ESLs can be disposed on the S/D regions and along sidewalls of the gate structures. In some embodiments, the stress liners can be disposed on the ESLs and the ILD layers can be disposed on the stress liners. The stress liners exert pressure on the gate structures, which is transferred as longitudinal compressive stress in the nanostructured channel regions. In some embodiments, the stress liners can include a silicon oxide, a silicon germanium oxide, a germanium oxide, or other suitable oxides of a semiconductor material.

In some embodiments, a semiconductor device includes a substrate, a nanostructured channel region disposed on the substrate, a gate structure surrounding the nanostructured channel region, a S/D region disposed adjacent to the nanostructured channel region, an ESL disposed on the S/D region, a stress liner disposed on the etch stop layer and configured to provide compressive stress in the nanostructured channel region, an ILD layer disposed on the stress liner, and a contact structure disposed in the S/D region, ESL, stress liner, and ILD layer.

In some embodiments, a semiconductor device includes a substrate, a fin structure disposed on the substrate, a gate structure disposed on the fin structure, a S/D region disposed adjacent to the fin structure, and a stack of dielectric layers disposed on the S/D region. The stack of dielectric layers includes a first dielectric layer disposed on the S/D region, a second dielectric layer disposed on the first dielectric layer and configured to provide compressive stress in a fin region of the fin structure, and a third dielectric layer disposed on the second dielectric layer. The materials of the first, second, and third dielectric layers are different from each other.

In some embodiments, a method includes forming first and second nanosheet stacks on a substrate, forming first and second polysilicon structures on the first and second nanosheets stacks, respectively, forming first and second S/D regions adjacent to the first and second nanosheets stacks, depositing a semiconductor layer on the first and second polysilicon structures and on the first and second S/D regions, depositing a dielectric layer on the semiconductor layer, performing a thermal anneal process on the dielectric layer and the semiconductor layer, and replacing the first and second polysilicon structures and sacrificial layer in the first and second nanosheet stacks with first and second gate structures.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a substrate;
a nanostructured channel region disposed on the substrate;
a gate structure surrounding the nanostructured channel region;
a source/drain (S/D) region disposed adjacent to the nanostructured channel region;
an etch stop layer (ESL) disposed on the S/D region;
a stress liner disposed on the etch stop layer and configured to provide compressive stress in the nanostructured channel region;
an inter-layer dielectric (ILD) layer disposed on the stress liner; and
a contact structure disposed in the S/D region, ESL, stress liner, and ILD layer.

2. The semiconductor device of claim 1, wherein the stress liner comprises an oxide of a semiconductor layer.

3. The semiconductor device of claim 1, wherein the stress liner comprises a silicon oxide layer, a germanium oxide layer, or a silicon germanium oxide layer.

4. The semiconductor device of claim 1, wherein the stress liner comprises a concentration of germanium atoms of about 1 atomic % to about 50 atomic %.

5. The semiconductor device of claim 1, wherein the stress liner comprises carbon, nitrogen, or fluorine atoms with a concentration of about 0.1 atomic % to about 5 atomic %.

6. The semiconductor device of claim 1, wherein the stress liner comprises:
a first liner portion in contact with the ESL and comprising a first concentration of oxygen atoms; and
a second liner portion in contact with the ILD layer and comprising a second concentration of oxygen atoms higher than the first concentration of oxygen atoms.

7. The semiconductor device of claim 1, wherein the stress liner comprises:
a first liner portion in contact with the ESL and comprising a first concentration of silicon or germanium atoms; and
a second liner portion in contact with the ILD layer and comprising a second concentration of silicon or germanium atoms lower than the first concentration of silicon or germanium atoms.

8. The semiconductor device of claim 1, wherein the stress liner comprises:
a first liner portion comprising an oxygen-free silicon, germanium, or silicon germanium layer; and
a second liner portion comprising a silicon oxide layer, a germanium oxide layer, or a silicon germanium oxide layer.

9. The semiconductor device of claim 1, wherein the stress liner comprises:
a first liner portion comprising a first concentration of silicon or germanium atoms higher than a first concentration of oxygen atoms; and
a second liner portion comprising a second concentration of silicon or germanium atoms lower than a second concentration of oxygen atoms.

10. The semiconductor device of claim 1, wherein a bottom surface of the stress liner is disposed at a distance of about 15 nm to about 25 nm above a top surface of the nanostructured channel region.

11. A semiconductor device, comprising:
a substrate;
a fin structure disposed on the substrate;
a gate structure disposed on the fin structure;
a source/drain (S/D) region disposed adjacent to the fin structure; and
a stack of dielectric layers, disposed on the S/D region, comprising:
a first dielectric layer disposed on the S/D region;
a second dielectric layer disposed on the first dielectric layer and configured to provide compressive stress in a fin region of the fin structure; and
a third dielectric layer disposed on the second dielectric layer, wherein materials of the first, second, and third dielectric layers are different from each other.

12. The semiconductor device of claim 11, wherein the first and third dielectric layers comprise germanium-free oxide layers; and
the second dielectric layer comprises a germanium-based oxide layer.

13. The semiconductor device of claim 11, wherein the second dielectric layer comprises a concentration of germanium atoms of about 1 atomic % to about 50 atomic %.

14. The semiconductor device of claim 11, wherein the second dielectric layer comprises carbon, nitrogen, or fluorine atoms with a concentration of about 0.1 atomic % to about 5 atomic %.

15. The semiconductor device of claim 11, wherein the second dielectric layer comprises:
a first portion comprising a first concentration of oxygen atoms; and
a second portion comprising a second concentration of oxygen atoms higher than the first concentration of oxygen atoms.

16. The semiconductor device of claim 11, wherein the second dielectric layer comprises a thickness of about 2 nm to about 10 nm.

17. A method, comprising:
forming first and second nanosheet stacks on a substrate;
forming first and second polysilicon structures on the first and second nanosheets stacks, respectively;
forming first and second source/drain (S/D) regions adjacent to the first and second nanosheets stacks;
depositing a semiconductor layer on the first and second polysilicon structures and on the first and second S/D regions;
depositing a dielectric layer on the semiconductor layer;
performing a thermal anneal process on the dielectric layer and the semiconductor layer; and
replacing the first and second polysilicon structures and sacrificial layer in the first and second nanosheet stacks with first and second gate structures.

18. The method of claim 17, wherein depositing the semiconductor layer comprises depositing an amorphous silicon layer, an amorphous germanium layer, or a silicon germanium layer.

19. The method of claim 17, further comprising removing a portion of the semiconductor layer from the first polysilicon layer and the first S/D region.

20. The method of claim 17, further comprising depositing an etch stop layer on the first and second polysilicon structures and on the first and second S/D regions prior to depositing the semiconductor layer.
